(19) United States
(12) Patent Application Publication
(10) Pub. No.: US 2026/0353905 A1
(43) Pub. Date: Nov. 5, 2026

(54) PEROVSKITE SOLAR CELLS WITH STRAIN-RELEASE LAYERS

(71) Applicant: The Trustees of Princeton University, Princeton, NJ (US)

(72) Inventors: Tianran LIU, Princeton, NJ (US); Xiaoming ZHAO, Princeton, NJ (US); Yueh-Lin LOO, Princeton, NJ (US)

(73) Assignee: The Trustees of Princeton University, Princeton, NJ (US)

(21) Appl. No.: 19/101,950

(22) PCT Filed: Aug. 9, 2023
(86) PCT No.: PCT/US2023/029808

§ 371 Date: Feb. 7, 2025

Related U.S. Application Data
(60) Provisional application No. 63/396,280, filed on Aug. 9, 2022.

(51) Int. Cl. H10K 30/40; H10K 30/85; H10K 30/86; H10K 71/12; H10K 85/40; H10K 85/60

(52) U.S. Cl. CPC H10K 30/40; H10K 30/85; H10K 30/86; H10K 71/12; H10K 85/40; H10K 85/633; H10K 85/626

(57) ABSTRACT

An interfacial lattice distortion is caused by the mismatch in thermal expansion coefficients between the perovskite layer and underlying electron transport layer (ETL) during thermal annealing and cool down. The lattice distortion in the perovskite film near the ETL interface can in turn induce defect formation that affects the interfacial charge transfer and accelerates polymorphic transformation of perovskites. To suppress lattice distortion, disclosed herein is the use of strain-release layers (SRLs) comprising, e.g., an oxysilane derivative, at the interface between CsPbI₃ and the underlying TiO₂ ETL in CsPbI₃ perovskite films. It was found that the SRLs are effective at suppressing lattice distortion near its interface with CsPbI₃, resulting in an enhanced efficiency of 20.1% and improved stability (T₉₀=1800 h) for encapsulated devices tested at maximum power point conditions under continuous illumination.

### CROSS-REFERENCE TO RELATED APPLICATIONS

The present application claims priority to U.S. Provisional Patent Application No. 63/396,280, filed Aug. 9, 2022, the contents of which are incorporated by reference herein in its entirety.

### STATEMENT REGARDING FEDERALLY SPONSORED RESEARCH OR DEVELOPMENT

This invention was made with government support under Grant Nos. DMR-1627453 and CMMI-1824674 awarded by the National Science Foundation. The government has certain rights in the invention.

### TECHNICAL FIELD

The present disclosure is drawn to perovskite solar cells, and specifically, to solar cells with a strain-release layer at a perovskite/inorganic ETL interface.

### BACKGROUND

Despite their rapidly increasing power-conversion efficiencies (PCEs), the operational stability of organic-inorganic hybrid perovskite solar cells (PSCs) remains a bottleneck for commercialization. All-inorganic CsPbI₃ is a promising alternative perovskite absorber, as its black phases (β and γ) have suitable properties for photovoltaic applications, and the absence of volatile organic cations, such as formamidinium (FA⁺) and methyl-ammonium (MA⁺), improves its chemical stability. However, the polymorphism of CsPbI₃ presents a new slate of stability challenges since the black β- and γ-CsPbI₃ phases can convert into a yellow δ-phase with poor photovoltaic properties under ambient conditions or when exposed to humidity. While strategies, such as alloying with Ge and Bi and surface passivation with long-chain organic ammonium halides, have been employed to increase the energy barrier for such polymorphic transformation, the operational stability of state-of-the-art β-CsPbI₃ solar cells remains inferior to their hybrid counterparts.

### BRIEF SUMMARY

In various aspects, a perovskite solar cell (PSC) may be provided. The PSC may have various structures, such as a conventional structure or an inverted structure.

The PSC in the conventional structure comprises or consists of: (i) a transparent electrode; (ii) an optional electron transport layer (ETL) above the transparent electrode; (iii) a photo-absorbing layer above the optional ETL, the photo-absorbing layer comprising three-dimensional halide perovskites, double perovskites, two-dimensional perovskites or a combination thereof; (iv) an optional hole transport layer (HTL) above the photo-absorbing layer; and (v) a second electrode above the optional hole transport layer.

The PSC in the inverted structure comprises or consists of: (i) a transparent electrode; (ii) an optional HTL above the transparent electrode; (iii) a photo-absorbing layer above the HTL, the photo-absorbing layer comprising a three-dimensional halide perovskite, double perovskite, two-dimensional perovskite, or a combination thereof; (iv) an optional ETL or a buffer layer above the photo-absorbing layer; and (v) a second electrode above the ETL or buffer layer.

These structures can generally be described as comprising or consisting of a photovoltaic composite layer between a transparent electrode and a second electrode, where the photovoltaic composite layer comprises or consists of a photo-absorbing structure between an ETL and an HTL.

The PSC may include a strain-release layer (SRL) coupled to an electrode, ETL, or HTL. The PSC may include a photoactive perovskite layer coupled to the SRL. Thus, the SRL may be sandwiched between the electrode, ETL or HTL and the photoactive perovskite layer.

The SRL may comprise or consist of an oxysilane derivatives, perylene or a derivatie thereof, benzoic acid or a derivative thereof, a dye, phosphonic acid or a derivative thereof, and/or aminofunctionalized molecules. The oxysilane derivative may be an alkyl-trimethoxysilane, 3-aminopropyltriethoxysilane, or γ-mercaptopropyltrimethoxysilane. The SRL may include methyltrimethoxysilane (C0), propyltrimethoxysilane (C2), and/or butyltrimethoxysilane (C3). The alkyl-trimethoxysilane may include an alkyl having a carbon chain at least 3 carbons in length. The SRL may consist of butyltrimethoxysilane (C3).

Advantageously, the transparent electrode may be indium tin oxide (ITO), fluorine doped tin oxide (FTO), indium zinc oxide, InZnAIO, ZnALO, cadmium oxide, zirconium indium oxide, gallium zinc oxide, graphene, graphene oxide, a conductive nanotube, a conductive nanoparticle, graphite, carbon nanotube, carbon, Ag, Al, Au, Mo, Cu, Ni, Ca, Li, poly(3,4-ethylenedioxythiophene) polystyrene sulfonate (PEDOT:PSS) or a combination thereof and/or the ETL is an oxide of a post-transition metal (such as TiO₂ or SnO₂), ZnO, ZnSnO₄, Cs₂CO₃, BaTiO₃, SrTiO₃, MgTiO₃, BaSnO₃, CdS, ZnTiO₃, WO₃, a conductive nanotube, a conductive nanoparticle, fullerene and its derivatives, self-assembled monolayers, MXene (2D transition metal carbides and nitrides with a composition of Mₙ₊₁XₙTₓ), indium gallium zinc oxide (InGaZnO₄), gallium nitride (GaN), niobium pentoxide (Nb₂O₅), In₂S₃, SnS₂, Bi₂S₃, MoS₂, WS₂, reduced graphene oxide, perylene diimide and its derivatives, naphthalene diimide and its derivatives, azaacene and its derivatives, n-type conjugated polymers, bathocuproine, bathophenanthroline, 2,2′,2″-(1,3,5-Benzinetriyl)-tris(1-phenyl-1-H-benzimidazole) (TPBi), tris[2,4,6-trimethyl-3-(pyridine-3-yl)phenyl]borane (3TPYMB), 3,3′,5,5′-tetra[(m-pyridyl)-phen-3-yl]biphenyl(BP4mPy), Tris(δ-hydroxyquinoline)aluminum (III) (Alq₃), N,N′-Bis(naphthalen-1-yl)-N,N′-bis(phenyl)benzidine (NPD), 4,4′-Bis(N-carbazolyl)-1,1′-biphenyl (CBP), N,N′-Bis(3-methylphenyl)-N,N′-diphenylbenzidine (TPD), Tris(4-carbazoyl-9-ylphenyl)amine (TCTA), 1,1-Bis[(di-4-tolylamino)phenyl]cyclohexane (TAPC), 1,3,5-Tris(3-pyridyl-3-phenyl)benzene (TmPyPB), Hexaazatriphenylenehexacarbonitrile (HATCN), a derivative thereof, or a doped layer thereof, or a combination thereof and/or the HTL comprises 2,2′,7,7′-tetrakis(N,N-di-p-methoxyphenyl-amine)-9,9′-spirobifluorene (spiro-OMeTAD), Pedot:PSS, Poly(3-hexylthiophene-2,5-diyl) (P3HT), Poly(triaryl amine) (PTAA), NiOₓ, CuSCN, Cu₂O, CuOₓ, CuO, MoOₓ, NiPc, CuPc, VOₓ, V₂Oₓ, Cr, CrOₓ, Co₃O₄, CoOₓ, Co_{1-y}Cu_{y}Oₓ, reduced graphene oxide, Alq₃, NPD, CBP, TPD, TCTA, TAPC, BP4mPy, TmPyPB, HATCN, Poly[(9,9-bis(3′-(N,N-dimethylamino) propyl)-2,7-fluorene)-alt-2,7-(9,9-dioctylfluorene)](PFN), self-assembled monolayers, a conductive nanoparticle, a conductive nanotube, p-type conjugated polymers, a derivative thereof, or a doped layer thereof, or a combination thereof.

The photoactive perovskite layer may include a three-dimensional halide perovskite (including organic, inorganic or hybrid), a double perovskite, a two-dimensional perovskite, or a combination thereof. The three-dimensional halide perovskite preferably has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof; B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof. The double perovskite preferably has the formula A₂BCX₆, where A is Cs, methylammonium (MA), formamidinium (FA), or combination thereof; B is Cu, Ag, Hg, Au, or a combination thereof; C is Sb, Bi, or a combination thereof; and X is F, Cl, Br, I, or a combination thereof. The two-dimensional perovskite preferably has the formula A₂Bₙ₋₁MₙX₃ₙ₊₁, where A is Cs, RNH₃ (where R is an organic group, such as C₆H₅(CH₂)₂), or a combination thereof; B is R′NH₃ (where R′ is an organic group, such as CH₃); Mis Pb, Sn, Ge, Bi, Sb, Cu, Au, Ag or a combination thereof; X is F, Cl, Br, I, or a combination thereof, n denotes that number of M-X sheets in each inorganic layer, and n is at least 2.

In various aspects, a method for depositing a strain-release layer (SRL) on a substrate may be provided. The method may include immersing the substrate into a solution for a period of time (such as at least 3 hours) or rinsing the substrate into a solution using a solution process method such as spin coating and blade coating. The solution may include a concentration (such as at least 5 mM) of a strain-relief material in a first volatile liquid. The method may include removing the substrate from the solution. The method may include rinsing the substrate in a second volatile liquid. The method may include drying the substrate under a flow of an inert gas.

The strain-relief material may include an oxysilane derivatives, perylene or a derivatie thereof, benzoic acid or a derivative thereof, a dye, phosphonic acid or a derivative thereof, and/or aminofunctionalized molecules.

The solution may consist of the concentration of the oxysilane derivative in the first volatile liquid.

The substrate may include an electrode, an electron transport layer (ETL) or a hole transport layer (HTL), such that the oxysilane derivative may be deposited on the ETL or HTL. The substrate may include an electrode, ETL or HTL, and a perovskite, such that the oxysilane derivative may be deposited on the perovskite.

The oxysilane derivative may be any oxysilane derivative as disclosed herein. The first volatile liquid may be isopropanol. The second volatile liquid may be isopropanol.

In various aspects, a method for improving perovskite solar cell (PSC) performance may be provided. The method may include suppressing lattice distortion. Suppressing lattice distortion may include introducing a strain-relief material (such as an oxysilane derivative as disclosed herein) as a strain-relaxation layer at the interface between a photoactive perovskite layer and an electrode, an electron transport layer or a hole transport layer, prior to thermal annealing.

### BRIEF DESCRIPTION OF DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is an illustration showing a schematic of an embodiment of a perovskite solar cell.

FIG. 2 is a flowchart showing an embodiment of a method for depositing a strain-release layer (SRL) on a substrate.

FIG. 3 is a graph showing characteristic spacing corresponding to the (110) plane of CsPbI₃ grown on TiO₂ without an SRL, and those with a C0, C2, or C3 SRL measured as a function of X-ray incidence angle using grazing-incidence wide-angle X-ray scattering (GIWAXS); for reference, the critical angle is 0.24°.

FIG. 4 is a graph showing Current density-voltage (J-V) characteristics of PSCs without an SRL, and those with a C0, C2, or C3 SRL performed in the reverse (i.e., positive to negative voltage) direction. Stabilized power-conversion efficiency (PCE) measurements of each PSC are shown in the inset.

FIG. 5 is a graph showing external quantum efficiency (EQE) of PSCs without an SRL, and those with a C0, C2, or C3 SRL performed in the reverse direction.

FIG. 6 is a graph showing integrated short circuit current (J_{SC}) of PSCs without an SRL, and those with a C0, C2, or C3 SRL performed in the reverse direction.

FIG. 7 is a graph showing the ratio of the (200) reflection of δ-CsPbI₃ (20=) 9.9° to the (110) reflection of β-CsPbI₃ (2θ=14.3°) extracted from the XRD patterns of (i) a glass/FTO/TiO₂/CsPbI₃ stack and (ii) a glass/FTO/TiO₂/C3/CsPbI₃ stack before and after aging for the indicated durations under continuous illumination in an inert atmosphere at 40 °C.

FIG. 8 is a graph showing normalized absorbance at 700 nm vs time extracted from absorbance spectra of (i) a glass/FTO/TiO₂/CsPbI₃ stack and (ii) a glass/FTO/TiO₂/C3/CsPbI₃ stack as a function of aging time under continuous illumination in an inert atmosphere at 40 °C.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

As used herein, the term “transparent” refers to a material that permits at least 50% of the incident electromagnetic radiation in relevant wavelengths to be transmitted through it, on average, across the relevant wavelengths.

As used herein, the term “volatile liquid” means a liquid that can evaporate under atmospheric pressure at room temperature (25 °C).

Interfacial lattice distortion of PSCs is caused by the mismatch in thermal expansion coefficients between the perovskite layer and underlying ETL during thermal annealing and cool down. The lattice distortion in the perovskite film near the ETL interface can in turn induce defect formation that affects the interfacial charge transfer and accelerates polymorphic transformation of perovskites.

Disclosed herein is improved absorber phase stability, performance, and lifetime in inorganic perovskite solar cells with strain-release layers at the perovskite/TiO₂ interface, an efficient solar cell device with a process to make it. The elimination of this lattice distortion in perovskite films involves introducing a strain-relief material, such as oxysilane derivatives, as SRLs at the interface between perovskite and the underlying ETL, HTL, or electrode.

In some embodiments, it was found that a C3 SRL is effective at suppressing lattice distortion near the interface of perovskite films, leading to improved stability and performance of PSCs. Including this C3 SRL improves power conversion efficiencies from 15.7% up to 20.1%, making these devices among the most efficient inorganic CsPbI₃ PSCs. Operational stability is also dramatically improved, leading to a T₉₀ of 1800 h for encapsulated PSCs tested at 40 °C under simulated one-sun illumination with maximum power point tracking—the longest lifetime reported for inorganic β-CsPbI₃ PSCs to-date.

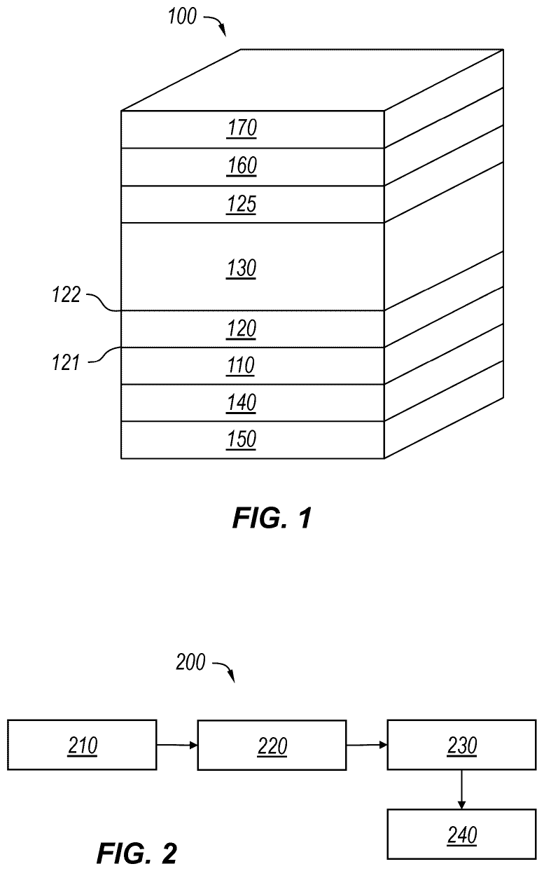

Referring to FIG. 1, an embodiment of a solar cell can be seen. The perovskite solar cell 100 may include an inorganic electron transport layer (ETL) 110. It is expected that the ETL may include known inorganic ETL material. Non-limiting examples include TiO₂, SnO₂, ZnO, ZnSnO₄, Cs₂CO₃, BaTiO₃, SrTiO₃, MgTiO₃, BaSnO₃, CdS, ZnTiO₃, WO₃, indium gallium zinc oxide (InGaZnO₄), gallium nitride (GaN), niobium pentoxide (Nb₂O₅), In₂S₃, SnS₂, Bi₂S₃, MoS₂, and/or WS₂. In some embodiments, the inorganic ETL may consist of TiO₂, SnO₂, ZnO, ZnSnO₄, Cs₂CO₃, BaTiO₃, SrTiO₃, MgTiO₃, BaSnO₃, CdS, ZnTiO₃, WO₃, indium gallium zinc oxide (InGaZnO₄), gallium nitride (GaN), niobium pentoxide (Nb₂O₅), In₂S₃, SnS₂, Bi₂S₃, MoS₂, WS₂ or a combination thereof. In a preferred embodiment, the ETL material may consist of TiO₂.

The perovskite solar cell may include at least one strain-release layer (SRL) 120, 125. In some embodiments, an SRL 120 may be coupled to the ETL. The SRL may include one or more strain-relief materials. The SRL may include an oxysilane derivative, perylene or a derivative thereof, benzoic acid or a derivative thereof, a dye, phosphonic acid or a derivative thereof, and/or aminofunctionalized molecules. In some embodiments, the SRL may consist of the oxysilane derivative, perylene and its derivatives, benzoic acid and its derivatives, dyes, phosphonic acid and its derivatives, and/or aminofunctionalized molecules. In some embodiments, the SRL may be comprise of the oxysilane derivative. In some embodiments, the oxysilane derivative may be an alkyl-trimethoxysilane.

As used herein, the term “[material] or a derivative thereof” includes the parent material as well as compounds based on the core structure of its parent, material, and may include one or more substitutions. As an example, a benzoic acid derivative may include one or more substitutions (e.g., carboxylic acid group(s) at any of the six carbons of the benzene ring). To this end, the benzoic acid derivative may be in the form of a salt or ester of benzoic acid (i.e., a benzoate). Phosphonic acid derivatives may include, e.g., alkyl phosphonic acids, alkyl phosphinic acids, alkyl phosphonate or alkyl phosphonate salts, and alkyl phosphinate or alkyl phosphinate salts. Perylene derivatives may include but are not limited to their alkyl perylenes, aryl perylenes, alkyne perylenes, aromatic perylenes, alkoxide perylenes, and aza perylenes.

The SRL may include methyltrimethoxysilane (CO). The SRL may include propyltrimethoxysilane (C2). The SRL may include butyltrimethoxysilane (C3). The SRL may include methyltrimethoxysilane (CO), propyltrimethoxysilane (C2), and/or butyltrimethoxysilane (C3). In some embodiments, the alkyl-trimethoxysilane may include an alkyl having a carbon chain at least 3 carbons in length. In some embodiments, the alkyl-trimethoxysilane may include an alkyl having a carbon chain at least 4 carbons in length. In some embodiments, the SRL may consist of butyltrimethoxysilane (C3).

In some embodiments, the oxysilane derivative may be 3-aminopropyltriethoxysilane. In some embodiments, the oxysilane derivative may be γ-mercaptopropyltrimethoxysilane.

The SRLs are effective at suppressing lattice distortion near the interface of perovskite films, leading to improved performance and stability of perovskite solar cells.

The perovskite solar cell may include a photoactive perovskite layer 130. The photoactive perovskite layer may be coupled to the SRL. As shown, the SRL may be sandwiched between the photoactive perovskite layer and the ETL. That is, in some embodiments, the ETL may be coupled to a first surface 121 of the SRL, and the photoactive perovskite layer may be coupled to a second surface 122 of the SRL opposite the first surface.

The photoactive perovskite layer may include a three-dimensional halide perovskite (including organic, inorganic or hybrid), a double perovskite, a two-dimensional perovskite, or a combination thereof. The three-dimensional halide perovskite preferably has the formula ABX₃, where A is Cs, Na, K, Rb, methylammonium (MA), formamidinium (FA), ethanediammonium, iso-propylammonium, dimethylammonium, guanidinium, piperidinium, pyridinium, pyrrolidinium, imidazolium, t-butylammonium, or a combination thereof; B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof. The double perovskite preferably has the formula A₂BCX₆, where A is Cs, methylammonium (MA), formamidinium (FA), or combination thereof; B is Cu, Ag, Hg, Au, or a combination thereof; C is Sb, Bi, or a combination thereof; and X is F, Cl, Br, I, or a combination thereof. The two-dimensional perovskite preferably has the formula A₂Bₙ₋₁MₙX₃ₙ₊₁, where A is Cs, RNH₃ (where R is an organic group, such as C₆H₅ (CH₂) 2), or a combination thereof; B is R′NH₃ (where R′ is an organic group, such as CH₃); M is Pb, Sn, Ge, Bi, Sb, Cu, Au, Ag or a combination thereof; X is F, Cl, Br, I, or a combination thereof, n denotes that number of M-X sheets in each inorganic layer, and n is at least 2.

The photoactive perovskite may be an all-inorganic perovskite. In some embodiments, A is Cs, Na, K, and/or Rb. In some embodiments, A is Cs. In some embodiments, B is Pb. In some embodiments, X is Cl, Br, and/or I. In some embodiments, X is I. In some embodiments, the perovskite layer may be comprised primarily of a black phase perovskite (e.g., beta and/or gamma-phase CsPbI₃).

The photoactive perovskite may be free of alloying materials. The photoactive perovskite may be free of surface treatments.

The PSC may include one or more additional layers.

The PSC may include a hole transport layer (HTL) 160 operably coupled to the photoactive perovskite layer. The photoactive perovskite layer may be disposed between the HTL and the ETL. Any appropriate HTL may be utilized here. Non-limiting examples include poly(triaryl amine) compounds and derivatives thereof (PTAA), 2,2′,7,7′-tetrakis-(N,N-di-4-methoxyphenylamino)-9,9′-spirobifluorene (Spiro-OMeTAD), 9-(2-ethylhexyl)-N₂, N₂, N₇, N₇-tetrakis(4-methoxyphenyl)-9H-carbazole-2,7-diamine (EH44), poly(N, N′-bis(4-butylphenyl)-N, N′-bis(phenyl)benzidine) (Poly-TPD), poly(3,4-ethylenedioxythiophene) polystyrene sulfonate (PEDOT:PSS), NiOₓ, MoO₃, V₂O₅, and combinations or stacks thereof.

In some embodiments, an SRL 125 may be disposed between the HTL and the photoactive perovskite. In some embodiments, the photoactive perovskite may be sandwiched between two SRLs. In some embodiments, only a single SRL is present.

The PSC may include a metal electrode layer 170 operably coupled to the HTL. The HTL. The HTL may be disposed between the metal electrode layer and the photoactive perovskite layer. The metal electrode layer may be any appropriate metal electrode material. In some embodiments, the electrode may include gold. In some embodiments, the electrode may include silver, aluminum, or copper.

The PSC may include a transparent conductive layer 140 operably coupled to the ETL. The ETL may be disposed between the transparent conductive layer and the SRL.

The transparent conductive layer may be any appropriate transparent conductive layer. Non-limiting examples include fluorine-doped tin oxide (FTO), indium tin oxide (ITO), aluminum-doped zinc oxide (AZO), and indium-doped zinc oxide (IZO) layers.

The PSC may include a transparent substrate 150. Here, the transparent substrate may be transparent to visible wavelengths (e.g., approximately 400 nm to 750 nm wavelengths). The transparent substrate may be transparent to at least some near infrared (NIR) wavelengths. The transparent substrate may be transparent to at least some ultraviolet A (UV-A) wavelengths.

The transparent substate may be glass, a rigid polymer, or a flexible polymer. The transparent substate may be coupled to the transparent conductive layer. For example, the transparent conductive layer may be a coating on the visible transparent substrate.

As will be understood, the configuration shown in FIG. 1 is only one possible arrangement for solar cells. For example, the PSC may be in a conventional structure or an inverted structure.

The PSC in the conventional structure comprises or consists of: (i) a transparent electrode; (ii) an electron transport layer (ETL) above the transparent electrode; (iii) a photo-absorbing layer above the ETL, a photo-absorbing layer comprising three-dimensional halide perovskites, double perovskites, two-dimensional perovskites or a combination thereof; (iv) a hole transport layer (HTL) above the photo-absorbing layer; and (v) a second electrode above the hole transport layer.

The PSC in the inverted structure comprises or consists of: (i) a transparent electrode; (ii) an HTL above the transparent electrode; (iii) a photo-absorbing layer above the HTL, the photo-absorbing layer comprising a three-dimensional halide perovskite, double perovskite, two-dimensional perovskite, or a combination thereof; (iv) an ETL or a buffer layer above the photo-absorbing layer; and (v) a second electrode above the ETL or buffer layer.

Advantageously, the transparent electrode is indium tin oxide (ITO), fluorine doped tin oxide (FTO), indium zinc oxide, InZnALO, ZnALO, cadmium oxide, zirconium indium oxide, gallium zinc oxide, graphene, graphene oxide, a conductive nanotube, a conductive nanoparticle, graphite, carbon nanotube, carbon, Ag, Al, Au, Mo, Cu, Ni, Ca, Li, poly(3,4-ethylenedioxythiophene) polystyrene sulfonate (PEDOT:PSS) or a combination thereof and/or the ETL is an oxide of a post-transition metal (such as TiO₂ or SnO₂), ZnO, ZnSnO₄, Cs₂CO₃, BaTiO₃, SrTiO₃, MgTiO₃, BaSnO₃, CdS, ZnTiO₃, WO₃, a conductive nanotube, a conductive nanoparticle, fullerene and its derivatives, self-assembled monolayers, MXene (2D transition metal carbides and nitrides with a composition of Mₙ₊₁XₙTₓ), indium gallium zinc oxide (InGaZnO₄), gallium nitride (GaN), niobium pentoxide (Nb₂O₅), In₂S₃, SnS₂, Bi₂S₃, MoS₂, WS₂, reduced graphene oxide, perylene diimide and its derivatives, naphthalene diimide and its derivatives, azaacene and its derivatives, n-type conjugated polymers, bathocuproine, bathophenanthroline, 2,2′,2″-(1,3,5-Benzinetriyl)-tris(1-phenyl-1-H-benzimidazole) (TPBi), tris[2,4,6-trimethyl-3-(pyridine-3-yl)phenyl]borane (3TPYMB), 3,3′,5,5′-tetra[(m-pyridyl)-phen-3-yl]biphenyl(BP4mPy), Tris(δ-hydroxyquinoline)aluminum (III) (Alq₃), N,N′-Bis(naphthalen-1-yl)-N,N′-bis(phenyl)benzidine (NPD), 4,4′-Bis(N-carbazolyl)-1,1′-biphenyl (CBP), N,N′-Bis(3-methylphenyl)-N,N′-diphenylbenzidine (TPD), Tris(4-carbazoyl-9-ylphenyl)amine (TCTA), 1,1-Bis[(di-4-tolylamino)phenyl]cyclohexane (TAPC), 1,3,5-Tris(3-pyridyl-3-phenyl)benzene (TmPyPB), Hexaazatriphenylenehexacarbonitrile (HATCN), a derivative thereof, or a doped layer thereof, or a combination thereof and/or the HTL comprises 2,2′,7,7′-tetrakis(N,N-di-p-methoxyphenyl-amine)-9,9′-spirobifluorene (spiro-OMeTAD), Pedot:PSS, Poly(3-hexylthiophene-2,5-diyl) (P3HT), Poly(triaryl amine) (PTAA), NiOₓ, CuSCN, Cu₂O, CuOₓ, CuO, MoOₓ, NiPc, CuPc, VOₓ, V₂Oₓ, Cr, CrOₓ, Co₃O₄, CoOₓ, Co_{1-y}Cu_{y}Oₓ, reduced graphene oxide, Alq₃, NPD, CBP, TPD, TCTA, TAPC, BP4mPy, TmPyPB, HATCN, Poly[(9,9-bis(3′-(N,N-dimethylamino) propyl)-2,7-fluorene)-alt-2,7-(9,9-dioctylfluorene)] (PFN), self-assembled monolayers, a conductive nanoparticle, a conductive nanotube, p-type conjugated polymers, a derivative thereof, or a doped layer thereof, or a combination thereof.

In various aspects, a method for depositing a strain-release layer (SRL) on a substrate may be provided. Referring to FIG. 2, a method 200 may include immersing 210 a substrate into a solution for a period of time. The period of time may be at least 2 hours. The period of time may be at least 4 hours. The period of time is preferably at least 3 hours. The period of time may be no more than 48 hours. The period of time is preferably at least 3 hours. The period of time may be no more than 24 hours. The period of time is preferably at least 3 hours. The period of time may be no more than 12 hours. The period of time is preferably at least 3 hours. The period of time may be no more than 6 hours. The solution may include a concentration of an oxysilane derivative in a first volatile liquid. The concentration is preferably at least 5 mM. The concentration may be at least 1 mM. The concentration may be at least 10 mM. The solution may consist of the concentration of the oxysilane derivative in the first volatile liquid.

Alternatively, or in addition to immersing, the method may include rinsing the substrate into a solution using a solution process method. The solution process method may include spin coating or blade coating.

The first volatile liquid may be any appropriate volatile liquid. The first volatile liquid may include an C1-C4 monoalcohol. In some embodiments, the first volatile liquid may include ethanol, butyl alcohol, and/or isopropanol. In some embodiments, the first volatile liquid may consist of isopropanol.

The substrate may include an electrode, an electron transport layer (ETL) or a hole transport layer (HTL), such that an oxysilane derivative may be deposited on, e.g., the ETL or HTL.

The oxysilane derivative may be any oxysilane derivative as disclosed herein.

The method may include removing 220 the substrate from the solution. The method may include rinsing 230 the substrate in a second volatile liquid.

The second volatile liquid may be the same as the first volatile liquid. The second volatile liquid may be different from the first volatile liquid. The second volatile liquid may be any appropriate volatile liquid. The second volatile liquid may include an C₁-C₄ monoalcohol. In some embodiments, the second volatile liquid may include ethanol, butyl alcohol, and/or isopropanol. In some embodiments, the second volatile liquid may consist of isopropanol.

The method may include drying 240 the substrate under a flow of an inert gas. The inert gas may be, e.g., N₂.

In various aspects, a method for improving perovskite solar cell (PSC) performance may be provided. The method may include suppressing lattice distortion. Suppressing lattice distortion may include introducing an oxysilane derivative (such as any oxysilane derivative as disclosed herein) as a strain-relaxation layer at the interface between a photoactive perovskite layer and an electrode, an electron transport layer or a hole transport layer, prior to thermal annealing

### Example

Apart from moisture-induced polymorphic transformation of CsPbI₃ films, defects induced by the lattice mismatch of CsPbI₃ and its underlying electron transport layer (ETL) have recently been shown to accelerate the polymorphic transformation of CsPbI₃. This interfacial lattice distortion is attributed to the order-of-magnitude mismatch in thermal expansion coefficients between CsPbI₃ and commonly used metal oxide ETLs during thermal annealing and cool down. In particular, inorganic perovskite CsPbI₃ requires a higher thermal annealing temperature (>200 °C) for conversion compared to its organic-inorganic hybrid counterparts, resulting in a much larger strain because the strain is proportional to temperature gradient.

Here, direct evidence can be shown for lattice distortion-induced phase transformation in encapsulated CsPbI₃ films aged under illumination and further demonstrate the elimination of such interfacial lattice distortion by introducing a strain-release layer at the interface between CsPbI₃ and an underlying TiO₂ ETL.

To fabricate a solar cell, pre-patterned FTO substrates were cleaned with deionized water, acetone, isopropanol, and UV-Ozone cleaner. For the electron transport layer, a compact titanium dioxide (TiO₂) layer of about 40 nm was deposited by spray pyrolysis of 7 mL 2-propanol solution containing 0.6 mL titanium diisopropoxide bis(acetylacetonate) solution and 0.4 mL acetylacetone at 450 °C using oxygen as the carrier gas. The substrates were then treated by UV-Ozone for 15 min. To fabricate SRL-modified surfaces, the TiO₂ compact films were immersed in a 5 mM solution of methyltrimethoxysilane (CO), propyltrimethoxysilane (C2), or butyltrimethoxysilane (C3) in isopropanol for 3 hours. After that, the substrates were rinsed in isopropanol and then dried under a flow of N₂. To prepare the CsPbI₃ active layer, a 0.6 M CsPbI₃ precursor solution was prepared by dissolving stoichiometric CsI, PbI₂, dimethylammonium iodine (DMAI) with 1:1:1.3 molar ratio in N-Dimethylformamide (DMF). The precursor solution was cast on the substrate and then spun at 2800 rpm for 30 s. Then the films were thermally annealed at 215 °C for 4.5 minutes in a dry box (23-25% R.H.). Subsequently, a hole transport layer was deposited on top of the active layer by spin-coating a Spiro-OMeTAD solution at 4000 rpm for 30 s. The Spiro-OMeTAD solution was prepared by dissolving the Spiro-OMeTAD in 1 mL chlorobenzene at a concentration of 60 mM, with the addition of 30 mM Bis(trifluoromethane) sulfonimide lithium salt (Li-TFSI) from a stock solution in acetonitrile and 200 mM of 4-tert-butylpyridine (t-BP). Finally, the solar cells were completed by thermal evaporation of 100-nm thick gold top electrodes. The active area (0.16 cm²) was defined using a shadow mask.

Thus, the SRLs in this example comprise ATMS derivatives with different chain lengths. X-ray photoelectron spectroscopy (XPS) measurements on the ETL surface after treatment show a pronounced Si signal and provide evidence of their adsorption on the ETL. These kinds of molecular layers are normally of a thickness of one or a few molecules, around 1 nm. This chemistry was selected because the surface condensation reaction between trimethoxysilane and hydroxyl groups is controlled, and the terminal methyl group interacts minimally with perovskites. However, other chemistries are equally applicable. With this series of silane compounds, the effects of systematically varying the spacer length on the phase stability of β-CsPbI₃ films and performance and lifetime of devices comprising these films can be probed.

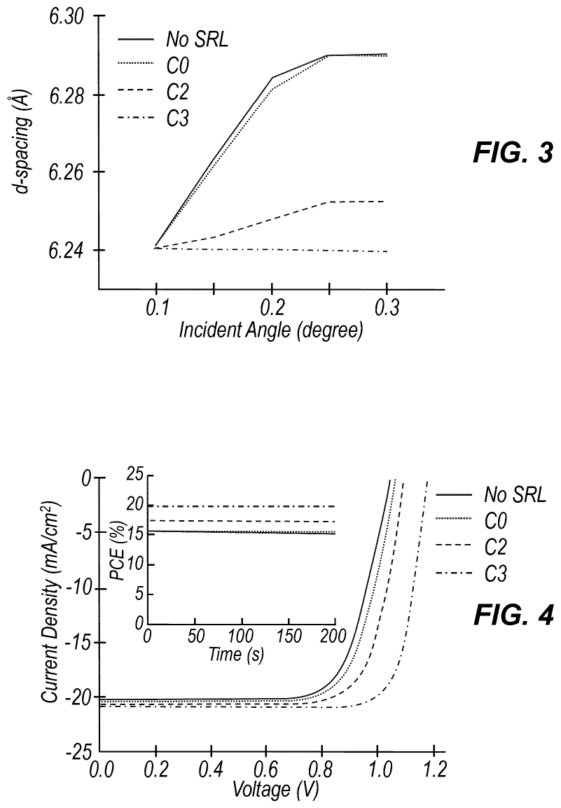

To measure their impact on the structure of β-CsPbI₃ films, depth-resolved grazing-incidence wide-angle X-ray scattering (GIWAXS) was performed by varying the X-ray incidence angle. The (110) reflection of CsPbI₃ in the X-ray diffraction (XRD) trace of the sample without an SRL and that with a CO SRL shifts to lower 2θ angles with increasing X-ray incident angle (0.1° to 0.3°) corresponding to an increase in the (110) planar spacing from 6.24 Å at the surface to 6.29 Å as the CsPbI₃ perovskite/ETL interface is approached. The characteristic spacing detected at the surface of CsPbI₃ is consistent with what had been reported for CsPbl₃ single crystals; it can thus be surmised that the expansion in the lattice spacing detected at the interface to stem from strain at the CsPbI₃ perovskite/ETL interface. This observation also suggests that strain is limited to the perovskite/ETL interface; the bulk of the perovskite film is not experiencing this strain. Employing SRLs with additional methylene units eliminates this depth dependence, with a characteristic (110) spacing of 6.25 and 6.24 Å at the interface for CsPbI₃ films deposited on a C2 and a C3 SRL, respectively. The incident angle-dependent (110) spacing of CsPbI₃ in the absence of an SRL and CsPbI₃ deposited atop a C0, C2, or C3 SRL are summarized in FIG. 3. The data show that SRLs with longer alkyl chain length can reduce perovskite lattice strain. It can be inferred that SRLs with a longer alkyl chain length provide a more flexible interface to be more effective at reducing the thermal expansion mismatch between the perovskite and ETL, leading to a less strained interface.

To investigate how the presence of SRLs impacts charge carrier dynamics in CsPbI₃, the transient time-resolved photoluminescence (TRPL) of glass/FTO/TiO₂/CsPbI₃ and glass/FTO/TiO₂/SRL/CsPbI₃ samples excited were measured from the glass side (more interface sensitive). The samples without an SRL and those with a CO SRL exhibit comparable photoluminescence (PL) lifetimes of 1.40±0.01 ns. In contrast, samples with a C2 and a C3 SRL demonstrate decreased PL lifetimes of 1.05±0.01 ns and 0.91±0.01 ns, respectively. As is known in the art, a faster PL decay suggests faster electron extraction, which is usually attributed to a less defective perovskite/ETL interface or better-aligned energy levels. The work functions (in eV) were determined as 3.77 (No SRL), 3.58 (CO), 3.55 (C2), and 3.57 (C3), with errors of ±150 meV. Since the work functions of these SRL-modified surfaces are comparable within the error of measurement, it is believed the incorporation of C2 and C3 SRLs results in fewer interfacial defects stemming from an elimination of interfacial lattice distortion. The TRPL measurements on glass/FTO/TiO₂/CsPbI₃ and glass/FTO/TiO₂/SRL/CsPbI₃ samples, excited from the perovskite film side (more bulk sensitive), demonstrate comparable PL decays, implying that the quality of perovskite films is similar across the samples examined and independent of interfacial strain.

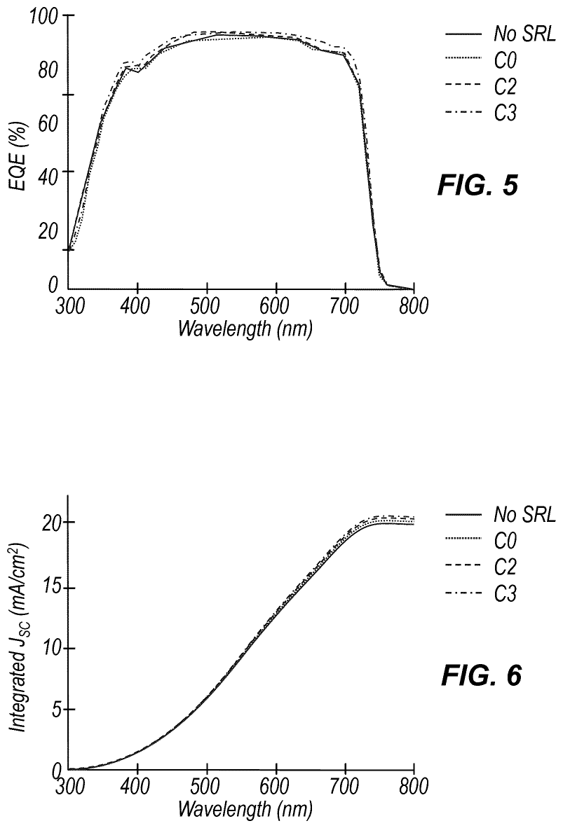

The fabricated PSCs, having the structure FTO/TiO₂/[SRL]/-CsPbI₃/Spiro-OMeTAD/Au were subjected to further tests. Representative current-voltage (J-V) characteristics and external quantum efficiency (EQE) spectra are shown in FIGS. 4-6, with stabilized output characteristics shown in the inset of FIG. 4 and full photovoltaic characteristics compiled in Table 1, below.

Table 1. Summary of the Champion and Average Photovoltaic Parameters of CsPbI₃ PSCs without an SRL, and Those with a C0, C2, or C3 SRL under Reverse Voltage Scan. The average and standard deviation (in brackets) were calculated based on the performance of at least 15 devices under each condition.

| SRL | | J_{SC} | J_{SC, EQE} | | |
|---|---|---|---|---|---|
| in | V_{OC} | (mA/ | (mA/ | FF | PCE |
| PSC | (V) | cm²) | cm²) | (%) | (%) |
| No | 1.05 (1.04 ± | 20.2 (20.2 ± | 19.9 | 74 (72 ± | 15.7 (15.2 ± |
| SRL | 0.01) | 0.1) | | 1) | 0.2) |
| C0 | 1.06 (1.06 ± | 20.3 (20.2 ± | 20.0 | 75 (73 ± | 16.1 (15.6 ± |
| | 0.01) | 0.2) | | 1) | 0.2) |
| C2 | 1.10 (1.09 ± | 20.6 (20.4 ± | 20.3 | 76 (76 ± | 17.3 (16.8 ± |
| | 0.01) | 0.2) | | 2) | 0.3) |
| C3 | 1.18 (1.17 ± | 20.8 (20.7 ± | 20.5 | 82 (80 ± | 20.1 (19.6 ± |
| | 0.02) | 0.1) | | 2) | 0.4) |

It was found that PSC efficiency scales with SRL alkyl chain length from 15.7% for a champion PSC without an SRL to 16.1%, 17.3%, and 20.1% for champion PSCs with a CO, C2, or C3 SRL, respectively. The PCE for the champion device with a C3 SRL is among the highest reported for inorganic CsPbI₃ PSCs to-date. The enhancement of PCE with the insertion of an SRL with increasing alkyl chain length is due primarily to progressive increases in open-circuit voltage (V_{OC}) from 1.05 V (no SRL) to 1.06 V (CO), 1.10 V (C2), and 1.18 V (C3) and a fill factor (FF) from 74% (no SRL) to 75% (CO), 76% (C2), and 82% (C3). This increase in Voc and FF with increasing alkyl chain length is consistent with a more rapid PL decay and implicates that solar cell performance improvements stem from fewer interfacial defects and improved carrier extraction at the perovskite/ETL inter-face. ince film morphology can also affect Voc and FF, scanning electron microscopy (SEM) was employed to examine the surface topology. No noticeable difference in surface topology is observed across these samples. In addition, ultraviolet photoemission spectroscopy (UPS) was also used to study if enhancements in the VOC and FF stem from TiO₂ work function changes with SRL incorporation. The work functions of these surfaces are comparable within the error of measurement and show no correlation with SRL alkyl chain length or PSC performance. Furthermore, it was observed that the PSC hysteresis factor decreases from 6.8% for a PSC without an SRL to 5.9%, 2.6%, and 1.8% for PSCs with a C0, C2, or C3 SRL. The extent of hysteresis is a direct manifestation of electron extraction at the perovskite/ETL interface.

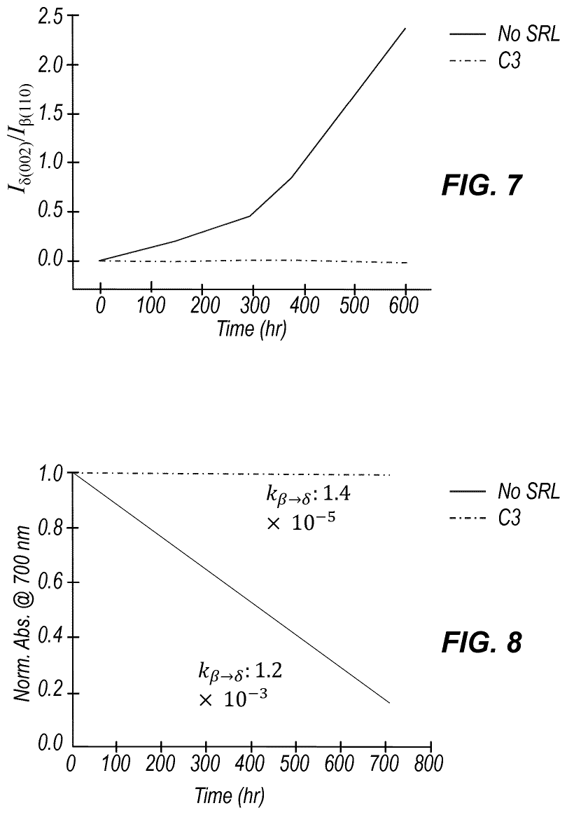

Given that C3 SRL gave the best photovoltaic performance and least CsPbI₃ lattice distortion at the perovskite/ETL interface, it was chosen to focus on comparisons between this system with control films/devices having no SRL for the remainder of this example. To evaluate the effect of SRL incorporation on the operational stability of PSCs, N₂-encapsulated solar cells were aged at their maximum power point (MPP) under continuous simulated AM1.5G illumination from a metal halide solar simulator according to ISOS-L-1I. Without an SRL, the PSCs degrade rapidly, with a quantified Too (i.e., the time it takes for PCE to degrade to 80% of its initial value) of just 209 h of continuous operation. In contrast, C3-modified solar cells retain>90% of their initial PCE after 1798 h, which linearly extrapolates to a T₈₀ lifetime of 3228±91 h, one of the longest reported for inorganic β-CsPbI₃ PSCs. To elucidate the device degradation mechanism, XRD was performed to track the structural evolution of CsPbI₃ perovskite films deposited on glass/TiO₂ substrates without an SRL and that with a C3 SRL before and after aging under continuous illumination in an inert atmosphere at 40 °C. The XRD trace of the sample without an SRL shows the (002) reflection of δ-CsPbI₃ (at 20=) 9.9° growing in intensity with aging at the expense of the (110) reflection of β-CsPbI₃ (at 20=) 14.2°. This evolution in the XRD indicates the formation of δ-CsPbI₃ at the expense of β-CsPbI₃. In the film employing the C3 SRL, negligible change in its XRD traces suggests suppressed polymorphic transformation in the presence of the C3 SRL. The intensity ratios of these reflections are plotted as a function of time in FIG. 7. It was observed that the Is/Ip of the CsPbI₃ film without an SRL increases from 0 to 2.4 after 596 h of aging while no change is observed in the ratio for the film with a C3 SRL.

To evaluate the polymorphic transformation rates of β-CsPbI₃ perovskite films, time-dependent UV-vis absorption measurements were performed on CsPbI₃ films aged under continuous illumination in an inert atmosphere at 40 °C. Aging under illumination produces a dramatic blue shift in the absorption onset of CsPbI₃ films without an SRL as they transform into δ-CsPbI₃, while the absorption spectra of CsPbI₃ films deposited on C3 SRLs are virtually unchanged. Since absorption of longer-wavelength photons is associated with the presence of β-CsPbI₃, the absorption at 700 nm was tracked as a function of time, as shown in FIG. 8, and fitted the data to quantify the transformation rate, k_{β→δ}. The introduction of a C₃ SRL decreases k_{β→δ} by nearly 2 orders of magnitude (1.2×10⁻³ h⁻¹ to 1.4× 10⁻⁵ h⁻¹); this decrease is comparable to the trends observed in the evolution of the XRD traces (see FIG. 7) and PSC stability data. While the azimuthally integrated GIWAXS trace of as-deposited films only show peaks corresponding to the (110) plane of the β-CsPbI₃ (e.g., q=1.01 Å⁻¹), the characteristic peaks of δ-CsPbI₃ (e.g., q=0.70 Å⁻¹) appear after aging under continuous 1-sun illumination at 40 °C, and are particularly pronounced at higher incident X-ray angles. The relative prevalence of δ-CsPbI₃ in the bulk compared to the surface of the perovskite film indicates that polymorphic transformation initiates near the perovskite/ETL interface and propagates toward the opposing surface of the CsPbI₃ layer.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

1. A perovskite solar cell (PSC), comprising:
a visibly transparent substrate comprising glass, a rigid polymer, or a flexible polymer; and
a first electrode deposited above the visibly transparent substrate;
an optional first transport layer deposited above the first electrode, the optional first transport layer consisting of either an electron transport layer (ETL) or a hole transport layer (HTL);
an optional first strain-release layer (SRL) deposited above the optional first transport layer;
a photoactive perovskite layer deposited above the optional first strain-release layer;
an optional second SRL deposited above the photoactive perovskite layer;
an optional second transport layer deposited above, the optional second transport layer consisting of the other of the ETL or the HTL; and
a second electrode deposited above the optional second transport layer; and
wherein at least one of the optional first SRL and the optional second SRL is present in the PSC.

2. The PSC according to claim 1, wherein the SRL comprises an oxysilane derivative, perylene or a derivative thereof, benzoic acid or a derivative thereof, a dye, phosphonic acid or a derivative thereof, an aminofunctionalized molecule, or a combination thereof.

3. The PSC according to claim 2, wherein the oxysilane derivative is an alkyl-trimethoxysilane, 3-aminopropyltriethoxysilane, or γ-mercaptopropyltrimethoxysilane.

4. The PSC according to claim 3, wherein the alkyl-trimethoxysilane comprises an alkyl having a carbon chain at least 3 carbons in length.

5. The PSC according to claim 3, wherein the SRL comprises methyltrimethoxysilane (CO), propyltrimethoxysilane (C2), and/or butyltrimethoxysilane (C3).

6. The PSC according to claim 5, wherein the SRL consists of butyltrimethoxysilane (C3).

7. The PSC according to claim 1, wherein the SRL comprises an oxysilane derivative.

8. The PSC according to claim 1, wherein the SRL consists of an oxysilane derivative.

9. The PSC according to claim 1, wherein the first electrode and/or second electrode is indium tin oxide (ITO), fluorine doped tin oxide (FTO), indium zinc oxide, InZnALO, ZnALO, a conductive nanotube, a conductive nanoparticle, cadmium oxide, zirconium indium oxide, gallium zinc oxide, graphene, graphene oxide, graphite, carbon nanotube, carbon, Ag, Al, Au, Mo, Cu, Ni, Ca, Li, poly(3,4-ethylenedioxythiophene) polystyrene sulfonate (PEDOT:PSS) or a combination thereof.

10. The PSC according to claim 1, wherein the electron transport layer comprises TiO₂, SnO₂, ZnO, ZnSnO₄, Cs₂CO₃, BaTiO₃, SrTiO₃, MgTiO₃, BaSnO₃, CdS, ZnTiO₃, WO₃, a conductive nanotube, a conductive nanoparticle, fullerene and its derivatives, self-assembled monolayers, MXene (2D transition metal carbides and nitrides with a composition of Mₙ₊₁XₙTₓ), indium gallium zinc oxide (InGaZnO₄), gallium nitride (GaN), niobium pentoxide (Nb₂O₅), In₂S₃, SnS₂, Bi₂S₃, MoS₂, WS₂, reduced graphene oxide, perylene diimide and its derivatives, naphthalene diimide and its derivatives, azaacene and its derivatives, n-type conjugated polymers, bathocuproine, bathophenanthroline, 2,2′,2″-(1,3,5-Benzinetriyl)-tris(1-phenyl-1-H-benzimidazole) (TPBi), tris[2,4,6-trimethyl-3-(pyridine-3-yl)phenyl]borane (3TPYMB), 3,3′,5,5′-tetra[(m-pyridyl)-phen-3-yl]biphenyl(BP4mPy), Tris(δ-hydroxyquinoline)aluminum (III) (Alq₃), N,N′-Bis(naphthalen-1-yl)-N,N′-bis(phenyl)benzidine (NPD), 4,4′-Bis(N-carbazolyl)-1,1′-biphenyl (CBP), N,N′-Bis(3-methylphenyl)-N,N′-diphenylbenzidine (TPD), Tris(4-carbazoyl-9-ylphenyl)amine (TCTA), 1,1-Bis[(di-4-tolylamino)phenyl]cyclohexane (TAPC), 1,3,5-Tris(3-pyridyl-3-phenyl)benzene (TmPyPB), Hexaazatriphenylenehexacarbonitrile (HATCN), a derivative thereof, or a doped layer thereof, or a combination thereof.

11. The PSC according to claim 1, wherein the hole transport layer comprises 2,2′,7,7′-tetrakis(N,N-di-p-methoxyphenyl-amine)-9,9′-spirobifluorene (spiro-OMeTAD), Pedot:PSS, Poly(3-hexylthiophene-2,5-diyl) (P3HT), Poly(triaryl amine) (PTAA), NiOx, CuSCN, Cu2O, CuOx, CuO, MoOx, NiPc, CuPc, VOx, V2Ox, Cr, CrOx, Co3O4, CoOx, Co1−yCuyOx, reduced graphene oxide, Alq₃, NPD, CBP, TPD, TCTA, TAPC, BP4mPy, TmPyPB, HATCN, Poly[(9,9-bis(3′-(N,N-dimethylamino) propyl)-2,7-fluorene)-alt-2,7-(9,9-dioctylfluorene)] (PFN), self-assembled monolayers, a conductive nanoparticle, a conductive nanotube, p-type conjugated polymers, a derivative thereof, or a doped layer thereof, or a combination thereof.

12. The PSC according to claim 1, wherein the photoactive perovskite layer is a three-dimensional halide perovskite, a double perovskite, a two-dimensional perovskite, or a combination thereof;
wherein the three-dimensional halide perovskite has a formula ABX₃, where A is Cs, Na, K, Rb, methylammonium (MA), formamidinium (FA),
ethanediammonium, iso-propylammonium, dimethylammonium, guanidinium, piperidinium, pyridinium, pyrrolidinium, imidazolium, t-butylammonium, or a combination thereof; B is Pb, Sn, Ge, Cu, Fe, Ga, Eu, Sr, Ti, Mn, Bi, Zn, Mg, Ca, Ba, Y, Yb, Co, In, Sb, Bi, Ag, Ni, Ho, Er, Tb, Sm, La, or a combination thereof; X is F, Cl, Br, I, or a combination thereof; and wherein the double perovskite has the formula A2BCX6, where A is Cs, methylammonium (MA), formamidinium (FA), or combination thereof; B is Cu, Ag, Hg, Au, or a combination thereof; C is Sb, Bi, or a combination thereof; and X is F, Cl, Br, I, or a combination thereof;
wherein the double perovskite has a formula A2BCX6, where A is Cs, methylammonium (MA), formamidinium (FA), or combination thereof; B is Cu, Ag, Hg, Au, or a combination thereof; C is Sb, Bi, or a combination thereof; and X is F, Cl, Br, I, or a combination thereof; and
wherein the two-dimensional perovskite has a formula A2Bn−1MnX3n+1, where A is Cs, RNH3 (where R is an organic group) or a combination thereof; B is R′NH₃ (where R′ is an organic group); M is Pb, Sn, Ge, Bi, Sb, Cu, Au, Ag or a combination thereof; X is F, Cl, Br, I, or a combination thereof, n denotes that number of M-X sheets in each inorganic layer, and n is at least 2.

13. A method for depositing a strain-release layer (SRL) on a substrate, comprising:
using a solution process method to rinse the substrate using a solution comprising a volatile liquid; and
optionally drying the substrate under a flow of an inert gas after rinsing using the volatile liquid,
wherein the solution comprises a concentration of an oxysilane derivative, perylene and its derivatives, benzoic acid and its derivatives, dyes, phosphonic acid and its derivatives, an aminofunctionalized molecule or a combination thereof in the volatile liquid.

14. (canceled)

15. A method for depositing a strain-release layer (SRL) on a substrate, comprising:
immersing the substrate into a solution for a period of time, the solution comprising a concentration of a strain-relief material in a first volatile liquid;
removing the substrate from the solution; and
rinsing the substrate in a second volatile liquid and drying under a flow of an inert gas,
wherein the strain-relief material comprises an oxysilane derivative, perylene or a derivative thereof, benzoic acid or a derivative thereof, a dye, phosphonic acid or a derivative thereof, an aminofunctionalized molecules, or a combination thereof.

16. The method of claim 15, wherein the oxysilane derivative is deposited on an electrode, electron transport layer (ETL), photoactive perovskite layer, or a hole transport layer (HTL).

17. The method of claim 15, wherein the solution consists of the concentration of the oxysilane derivative in the first volatile liquid.

18. The method of claim 15, wherein:
the period of time is at least 3 hours; and/or
the concentration is at least 5 mM.

19-21. (canceled)

22. The method of claim 15, wherein the first volatile liquid is isopropanol, the second volatile liquid is isopropanol, or both.

23. (canceled)

24. A method for improving perovskite solar cell (PSC) performance, comprising:
suppressing lattice distortion by introducing a strain-relief material as a strain-relaxation layer as an interface between a photoactive perovskite layer and an inorganic electron transport layer, prior to thermal annealing;
wherein the strain-relief material comprises an oxysilane derivative, perylene or a derivative thereof, benzoic acid or a derivative thereof, a dye, phosphonic acid or a derivative thereof, an aminofunctionalized molecule, or a combination thereof.

25. (canceled)
